(19) United States
(12) Patent Application Publication
(10) Pub. No.: US 2006/0019445 A1
(43) Pub. Date: Jan. 26, 2006

(54) NON-VOLATILE MEMORY AND MANUFACTURING METHOD THEREOF

(76) Inventor: Tung-Po Chen, Taichung (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/907,279

(22) Filed: Mar. 28, 2005

(30) Foreign Application Priority Data
Jul. 21, 2004 (TW) 93121701

(51) Int. Cl. H01L 21/336

(52) U.S. Cl. 438/257

(57) ABSTRACT

A method of manufacturing a non-volatile memory is provided. A substrate is provided and then a plurality of stacked gate structures is formed on the substrate. Each stacked gate structure includes a tunneling dielectric layer, a floating gate, a first inter-gate dielectric layer, a control gate and a cap layer. A source region is formed in the substrate and then a second inter-gate dielectric layer is formed over the substrate. A plurality of polysilicon select gates is formed on one side of the stacked gate structures. The select gates connect the stacked gate structures together to form a memory cell column. A spacer is formed on each sidewall of the memory cell column. A drain region is formed in the substrate on one side of the memory cell column. A silicidation process is carried out to convert the polysilicon constituting the select gate into silicide material.

### CROSS-REFERENCE TO RELATED APPLICATION

This application claims the priority benefit of Taiwan application serial no. 93121701, filed Jul. 21, 2004.

### BACKGROUND OF THE INVENTION

1. Field of the Invention

The present invention relates to a semiconductor device and manufacturing method thereof. More particularly, the present invention relates to a non-volatile memory and manufacturing method thereof.

2. Description of the Related Art

Electrically erasable programmable read only memory (EEPROM) is one type of non-volatile memory that allows multiple data writing, reading and erasing operations. Furthermore, the stored data will be retained even after power to the device is removed. With these advantages, EEPROM has been broadly applied in personal computer and electronic equipment.

A typical EEPROM has a floating gate and a control gate fabricated using doped polysilicon. To prevent a typical EEPROM from over-erasing in an erase operation and produce data read-out errors, a select gate fabricated using doped polysilicon is formed on the sidewall of the control gate and the floating gate and above the substrate. In other words, a select gate transistor is set up on one side of the memory unit.

However, when a non-volatile memory having the aforementioned select gate structures is used to form a NAND gate array, the width of the select gate depends on the difference between the gap between two adjacent control gates and the thickness of the spacers (roughly 200 Å˜300 Å). Hence, with an identical line/space separation, the select gate has a width smaller than the control gate. As the level of integration of semiconductor device increases, electrical resistance of the select gate will shoot up and the reverse narrow width effect (intensified boron diffusion) together with the short channel effect will limit the maximum threshold voltage reached. In other words, a select transistor having a high threshold voltage value is difficult to produce using a simple implant process. As a result, the memory operation speed will slow down and overall device performance of the device will drop.

On the other hand, because the select gates and the control gates are often fabricated using doped polysilicon or polysilicon silicide (polycide) material, the electrical resistance of the serially connected doped polysilicon or tungsten silicide gates will add to too much electrical resistance. Although low electrical resistance materials such as tungsten/tungsten nitride and tungsten/titanium nitride can replace the doped polysilicon or polycide, there are significant changes in the properties as well as the method of forming the device.

### SUMMARY OF THE INVENTION

Accordingly, at least one objective of the present invention is to provide a non-volatile memory and manufacturing method thereof that can lower the electrical resistance of the select gate of a select transistor and increase the threshold voltage of the select transistor.

At least a second objective of the present invention is to provide a non-volatile memory and manufacturing method thereof that can increase the level of integration of internal devices and improve the electrical performance of the devices.

To achieve these and other advantages and in accordance with the purpose of the invention, as embodied and broadly described herein, the invention provides a method of manufacturing a non-volatile memory. First, a substrate is provided and then a plurality of stacked gate structures is formed over the substrate. Each stacked gate structure includes a tunneling dielectric layer, a floating gate, a first inter-gate dielectric layer, a control gate, a cap layer and a first spacer. A source region is formed in the substrate. The source region is disposed in the substrate on an outer side of the stacked gate structures. Thereafter, a second inter-gate dielectric layer is formed over the substrate and then a plurality of polysilicon select gates is formed on one side of the stacked gate structures. The select gates connect the stacked gate structures together to form a memory cell column. The select gates are formed using polysilicon. After that, an insulating layer is formed over the substrate and then a portion of the insulating layer is removed to form a second spacer on each sidewall of the memory cell column. A drain region is formed in the substrate. The drain region is disposed in the substrate on the other outer side of the stacked gate structures. A silicidation process is carried out to convert the polysilicon constituting the select gate into silicide material.

In the aforementioned method of fabricating the non-volatile memory, the step of forming a stacked gate structure includes sequentially depositing a first dielectric layer, a first conductive layer, a second dielectric layer, a second conductive layer and a third dielectric layer over the substrate. Thereafter, the third dielectric layer and the second conductive layer are patterned to form a cap layer and a control gate. A first spacer is formed on the sidewalls of the cap layer and the control gate. After that, the second dielectric layer, the first conductive layer, the first dielectric layer are patterned to form a first inter-gate dielectric layer, a floating gate and a tunneling dielectric layer.

In the aforementioned method of fabricating the non-volatile memory, the silicidation process for converting the polysilicon select gate into silicide material includes forming a cover layer over the substrate. Thereafter, the cover layer is patterned to expose the select gate. Next, a metallic layer is formed over the substrate and then an annealing process is carried out to initiate the reaction between the metallic layer and the select gate material to form a silicide layer. Finally, residual metallic material not having any reaction with the silicon material is removed.

In the present invention, the sheet resistance of the select gate is lowered when the select gate material changes from polysilicon into silicide (nickel silicide). Furthermore, before converting the select gate polysilicon into silicide, the dopant concentration of the doped polysilicon can be adjusted to increase the threshold voltage of the select transistor. In addition, the aforementioned method of fabricating the non-volatile memory can integrate with complementary metal-oxide-semiconductor (CMOS) process without major alterations.

The invention also provides an alternative method of manufacturing a non-volatile memory. First, a substrate is provided and then a plurality of stacked gate structures is formed over the substrate. Each stacked gate structure includes a tunneling dielectric layer, a floating gate, a first inter-gate dielectric layer, a control gate and a cap layer. The control gate is fabricated using doped polysilicon. A source region is formed in the substrate. The source region is disposed in the substrate on an outer side of the stacked gate structures. Thereafter, a second inter-gate dielectric layer is formed over the substrate and then a plurality of select gates is formed on one side of the stacked gate structures. The select gates connect the stacked gate structures together to form a memory cell column. The select gates are fabricated using polysilicon. A drain region is formed in the substrate. The drain region is disposed in the substrate on the other outer side of the stacked gate structures. After that, an insulating layer is formed over the substrate and then a portion of the insulating layer is removed to form a spacer on each sidewall of the memory cell column. After forming a cover layer over the substrate, the cover layer is patterned to expose the select gate and a portion of the second inter-gate dielectric layer. A portion of the second inter-gate dielectric layer and the cap layer are removed to form an opening that exposes the control gate. Finally, a silicidation process is carried out to convert the polysilicon constituting the select gate and the control gate into silicide material.

In the present invention, the sheet resistance of the control gate and the select gate are lowered when the control gate and the select gate material change from polysilicon into silicide (nickel silicide). Furthermore, before converting the control gate and the select gate polysilicon into silicide, the dopant concentration of the doped polysilicon can be adjusted to increase the threshold voltage of the select transistor. In addition, the aforementioned method of fabricating the non-volatile memory can integrate with complementary metal-oxide-semiconductor (CMOS) process without major alterations.

The present invention also provides a non-volatile memory. The non-volatile memory includes a substrate, a plurality of stacked gate structures, a plurality of select gate and a second inter-gate dielectric layer. The stacked gate structures are disposed on the substrate. Each stacked gate structure includes a tunneling dielectric layer, a floating gate, a first inter-gate dielectric layer and a control gate are stacked over the substrate. The select gates are disposed on one side of the stacked gate structures such that the stacked gate structures are connected serially together to form a memory cell column. The second inter-gate dielectric layer is disposed between the stacked gate structure and the select gate. The select gate is fabricated using a material including silicide.

In the present invention, silicide material is used to fabricate the select gate and/or the control gate. Hence, the sheet resistance of the select gate and/or the control gate is reduced and the performance of the device is improved. Furthermore, the concentration of dopants within the doped polysilicon layer can be adjusted before converting the polysilicon constituting the control gates and the select gates into silicide. Ultimately, the select transistor has a higher threshold voltage of operation.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A through 11 are schematic cross-sectional views showing the steps for fabricating a non-volatile memory according to one preferred embodiment of the present invention.

FIGS. 2A through 2C are schematic cross-sectional views showing the steps for fabricating a non-volatile memory according to another preferred embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

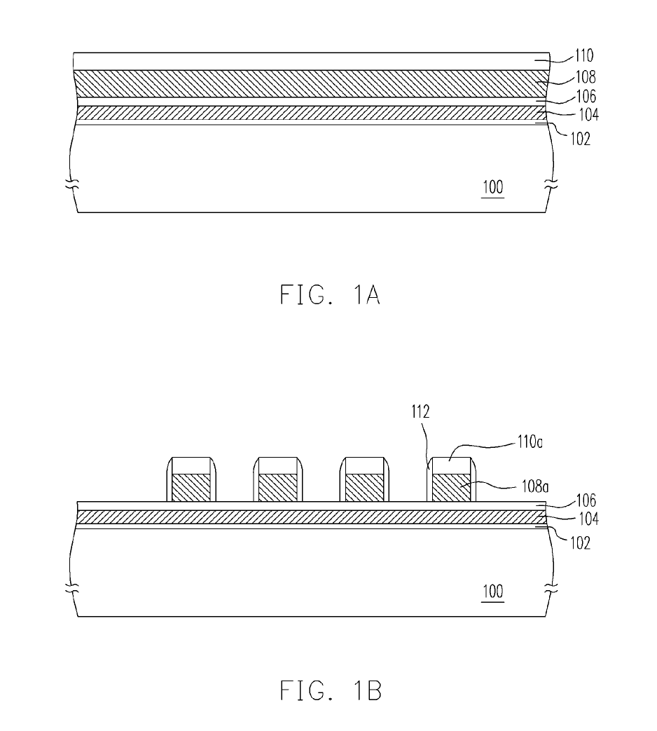

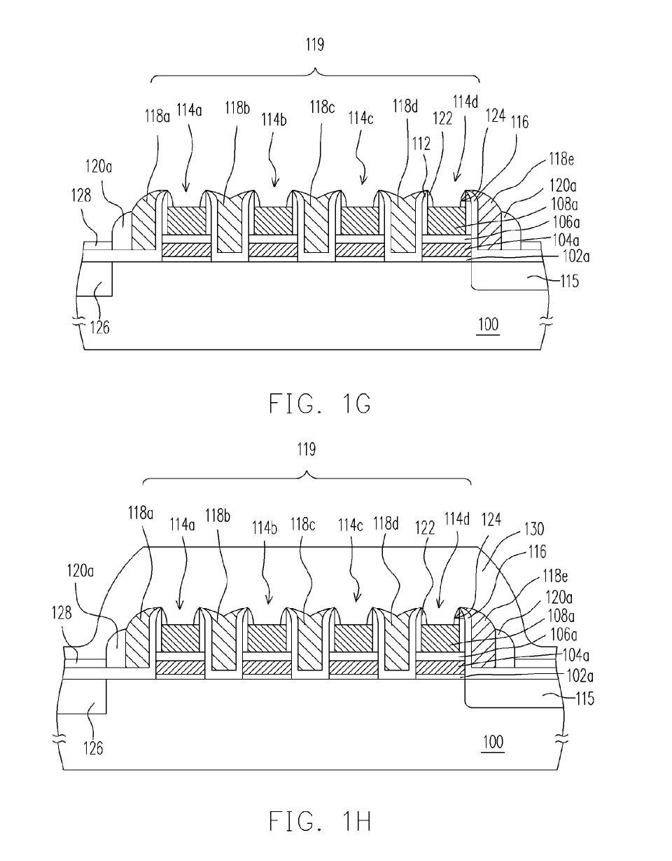

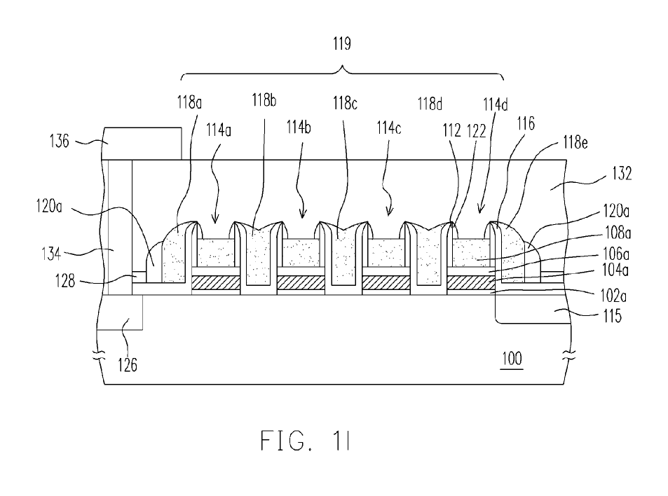

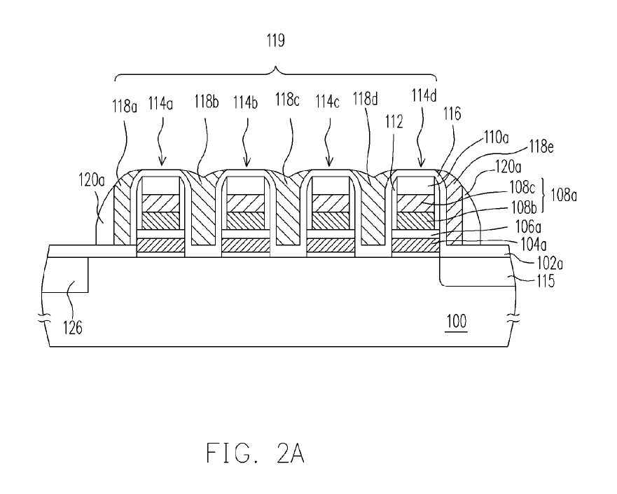

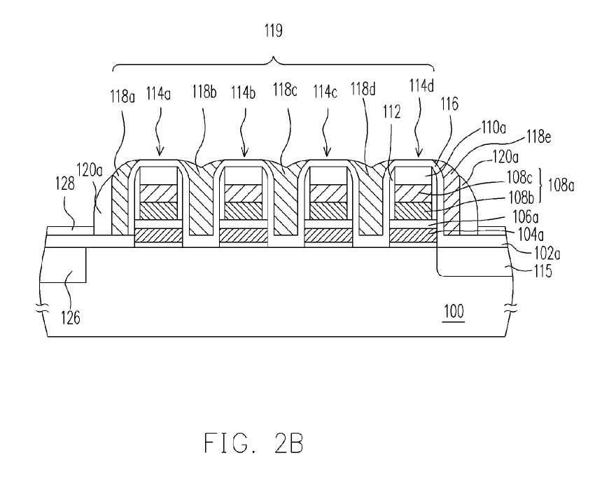

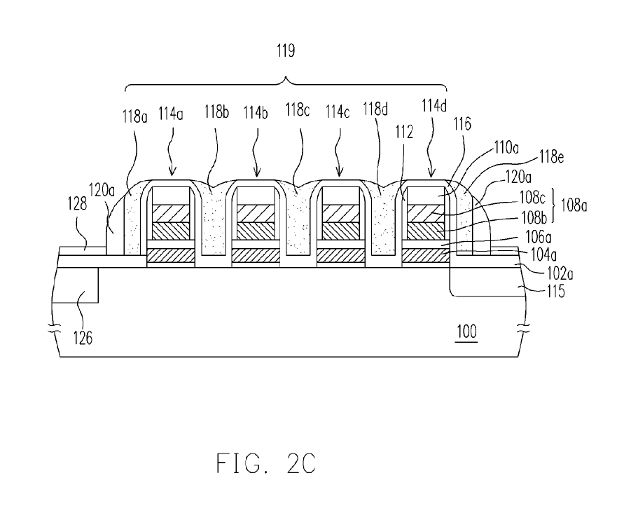

First, a method of manufacturing a non-volatile memory is provided. FIGS. 1A through 11 are schematic cross-sectional views showing the steps for fabricating a non-volatile memory according to one preferred embodiment of the present invention. The cross-sectional views shown in FIGS. 1A through 11 show only the changes in the active region.

As shown in FIG. 1A, a substrate 100 such as a silicon substrate is provided. Thereafter, a dielectric layer 102 is formed over the substrate 100. The dielectric layer 102 is, for example, a silicon oxide layer formed in a thermal oxidation process.

Thereafter, a conductive layer 104 is formed over the dielectric layer 102. The conductive layer 104 is, for example, a doped polysilicon layer formed by performing a chemical vapor deposition to form an undoped polysilicon layer and then implanting ions into the undoped polysilicon layer.

After that, a dielectric layer 106 is formed over the conductive layer 104. The dielectric layer 106 is, for example, an oxide/nitride/oxide composite layer. The dielectric layer 106 is formed, for example, by carrying out a thermal oxidation to form a silicon oxide layer over the conductive layer 104 and performing a chemical vapor deposition process to form a silicon nitride layer over the silicon oxide layer. Finally, a portion of the silicon nitride layer is oxidized to form another silicon oxide layer using wet hydrogen/oxygen gaseous mixture (H₂/O₂ gaseous mixture). Obviously, the dielectric layer 106 can also be a silicon oxide layer alone or an oxide/nitride composite layer.

Another conductive layer 108 is formed over the substrate 100. The conductive layer 108 is, for example, a doped polysilicon layer formed by performing a chemical vapor deposition to form an undoped polysilicon layer and implanting ions into the undoped polysilicon layer. Alternatively, the doped polysilicon layer is formed, for example, by performing a chemical vapor deposition process with in-situ ion implantation. Thereafter, a dielectric layer 110 is formed over the conductive layer 108. The dielectric layer 110 is, for example, a silicon nitride layer formed by performing a chemical vapor deposition process. Obviously, the dielectric layer 110 can also be a silicon oxide layer or a material layer fabricated from other dielectric materials.

As shown in FIG. 1B, the dielectric layer 110 and the conductive layer 108 are patterned to form a cap layer 110a and a conductive layer 108a. The cap layer 110 and the conductive layer 108a are formed, for example, by performing photolithographic and etching processes. The conductive layer 108a serves as a control gate of the memory. Thereafter, a spacer 112 is formed on the sidewalls of the cap layer 110a and the conductive layer 108a. The spacers 112 are, for example, silicon oxide layers formed by depositing insulating material over the substrate 100 and etching back the insulating layer thereafter. Obviously, the spacers can be a silicon nitride or some other material layers.

As shown in FIG. 1C, the dielectric layer 106, the conductive layer 104 and the dielectric layer 102 are patterned to form an inter-gate dielectric layer 106a, a conductive layer 104a and a tunneling dielectric layer 102a using the cap layer 110a and the conductive layer 108a as a mask. The conductive layer 104a serves as a floating gate of the memory. In other words, the conductive layer (the control gate) 108a, the inter-gate dielectric layer 106a, the conductive layer (the floating gate) 104a and the tunneling dielectric layer 102a together form a series of stacked gate structures 114a˜114d.

Thereafter, a patterned mask layer 117 is formed over the substrate 100. The patterned mask layer 117 exposes the area for forming a source region 115. Using the patterned mask layer 117 as a mask, a dopant implantation process is carried out to form a source region 115 in the substrate 100 on one side of the stacked gate structure 114d. The method of implanting dopants in the substrate 100 includes an ion implantation.

As shown in FIG. 1D, the patterned mask layer 117 is removed and then another inter-gate dielectric layer 116 is formed over the substrate 100. The inter-gate dielectric layer 116 is a high-temperature oxide layer, for example.

Thereafter, a conductive layer (not shown) is formed over the substrate 100. The conductive layer fill the gaps between neighboring stacked gate structures 114a˜114d. The conductive layer is, for example, a doped polysilicon layer formed by depositing undoped polysilicon material over the substrate 100 in a chemical vapor deposition process and then implanting ions into the polysilicon layer. Alternatively, the conductive layer is formed in a chemical vapor deposition process with in-situ ion implantation. After that, a portion of the conductive layer is removed to form select gates 118b˜118d between the stacked gate structures 114a˜114d and a select gate 118 and a conductive layer 118e on one side of the stacked gate structures 114a and 114b respectively. The inter-gate dielectric layer 116 between the select gates 118a 118d serves as a select gate dielectric layer. The stacked gate structures 114a 114d and the select gate 118a 118d together form a series of memory cell structures that are serially connected to form a memory cell column 119.

As shown in FIG. 1E, an insulating layer 120 is formed over the substrate 100. The insulating layer 120 is fabricated using a material having an identical etching selectivity as the cap layer 110a such as a silicon nitride layer. The insulating layer 120 is formed, for example, by performing a chemical vapor deposition process.

As shown in FIG. 1F, a portion of the insulating layer 120 is removed to form a spacer 120a on one side of the memory column 119 and one side of the conductive layer 118e. Thereafter, a drain 126 is formed in the substrate 100 (the substrate 100 on one side of the select gate 118a) on one side of the memory cell column 119. After that, a cover layer 128 is formed over the substrate 100. The cover layer 128 is fabricated using a material having an etching selectivity different from the inter-gate dielectric layer 116 such as silicon nitride, for example. The cover layer 128 having a thickness between 300 Å to 500 Å is, for example, formed in a chemical vapor deposition.

As shown in FIG. 1G, the cover layer 128 is patterned to expose the area for forming a silicide layer. Using the cover layer 128 as a mask, a portion of the inter-gate dielectric layer 116 and a portion of the cap layer 110a are removed to form openings 124 that exposes the conductive layers 108a. The openings 124 are formed, for example, by forming a patterned photoresist layer over the cover layer 128 to expose the area for forming the silicide layer and then etching the cover layer 128, the inter-gate dielectric layer 116 and the cap layer 110a in a single step. The method of removing a portion of the insulating layer 120, a portion of the inter-gate dielectric layer 116a and a portion of the cap layer 110a includes performing an anisotropic etching operation. Because a portion of the insulating layer 120, the inter-gate dielectric layer 116a and the cap layer 110a are removed in an anisotropic etching process, a spacer 122 is formed on the sidewalls of the spacers 112.

As shown in FIG. 1H, a metallic layer 130 is formed over the substrate 100. The metallic layer 130 is a layer of nickel formed in a physical vapor deposition process, for example. The metallic layer 130 is thick enough to produce a silicide layer when the polysilicon material constituting the conductive layer 108a (the control gate), the select gates 118a˜118d and the conductive layer 118e is converted into silicide material. Thereafter, an annealing operation is carried out to permit a reaction between silicon and metal so that the polysilicon material constituting the conductive layer 108a (the control gate), the select gates 118a˜118d and the conductive layer 118e is converted into silicide material. In other words, the material constituting the conductive layer 108a (the control gate), the select gates 118a˜118d and the conductive layer 118e is transformed into nickel silicide. In general, the sheet resistance of nickel silicide is unrelated to the line width but the work function is related to the dopant concentration within the polysilicon. Hence, the difference in work function between the silicon and the nickel silicide can be changed through the adjustment of dopant concentration within the doped polysilicon prior to forming the nickel silicide layer. Hence, the threshold voltage of the select transistor not only can be adjusted through dopant implantation, but also can be adjusted through the difference in work function between silicon and nickel silicide.

As shown in FIG. 11, the metallic layer not participating in the reaction with silicon material is removed. Thereafter, an inter-gate dielectric layer 132 is formed over the substrate 100 and a contact plug 134 for electrically connecting with the drain region 126 is formed in the inter-gate dielectric layer 132. After that, other processes are carried out to form a complete non-volatile memory. Since the remaining steps should be familiar to anyone skill in the art of semiconductor production, a detailed description of those steps is omitted.

In the aforementioned embodiment, the sheet resistance of the conductive layer 108a (the control gate) and the select gates 118a˜118d are lowered when the conductive layer 108a (the control gate) and the select gate 118a˜118d material change from polysilicon into nickel silicide. Furthermore, before converting the conductive layer 108a (the control gate) and the select gate 118a˜118d polysilicon into silicide, the dopant concentration of the doped polysilicon can be adjusted to increase the threshold voltage of the select transistor. In addition, the aforementioned method of fabricating the non-volatile memory can integrate with complementary metal-oxide-semiconductor (CMOS) process without major alterations.

In the aforementioned embodiment, four memory cell structures are serially connected together. However, the number of serially connected memory cell structures can be varied according to actual demand. For example, 32 to 64 memory cell structures can be serially connected together. In addition, although nickel silicide is the material constituting the control gates and the select gates in the aforementioned embodiment, other types of materials including titanium silicide, tantalum silicide, molybdenum silicide or cobalt silicide can be used as well.

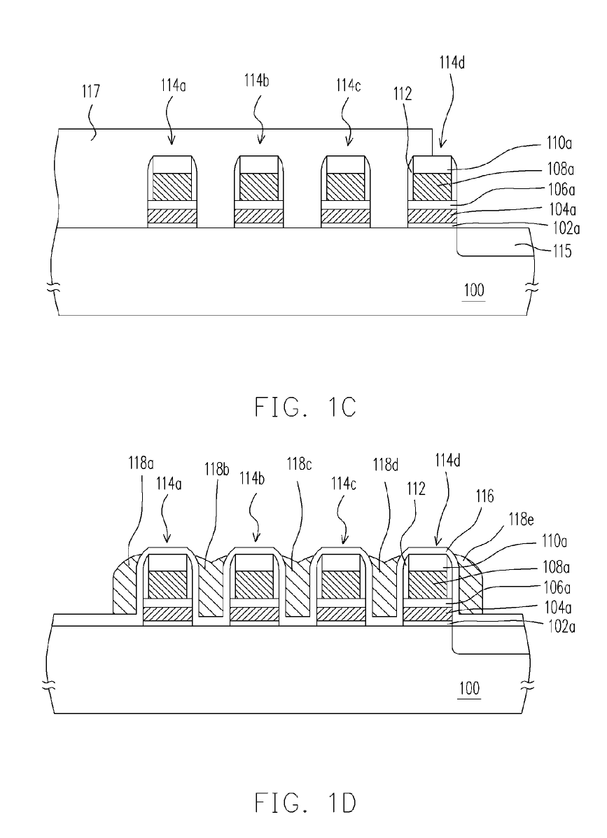

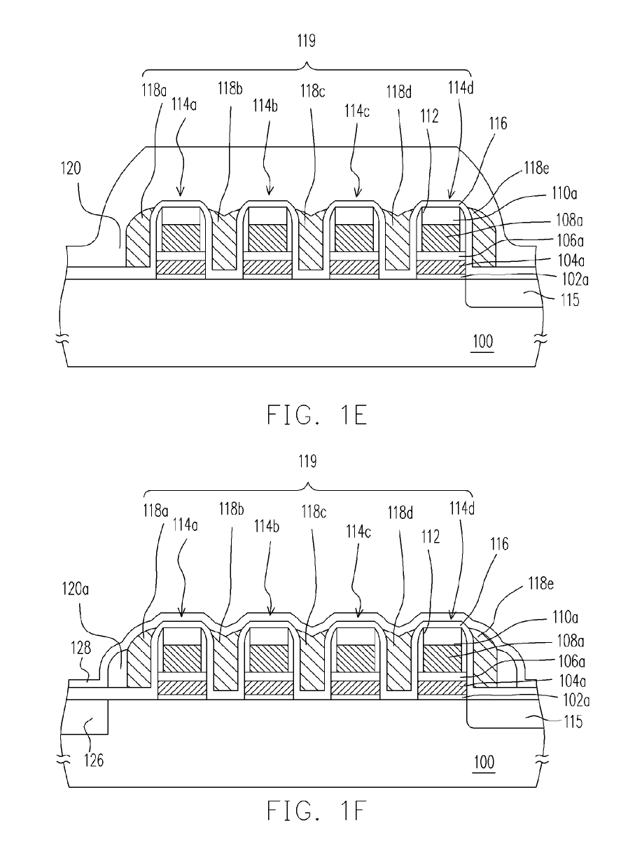

FIGS. 2A through 2C are schematic cross-sectional views showing the steps for fabricating a non-volatile memory according to another preferred embodiment of the present invention. In FIGS. 2A, 2B and 2C, those components identical to the ones in FIGS. 1A through 1G are labeled identically. In fact, FIG. 2A is a continuation from FIG. 1E.

First, as shown in FIG. 2A, the conductive layer 108a is a polycide layer including a doped polysilicon layer 108b and a silicide layer 108c. The cap layer 110a is, for example, a silicon oxide layer. After forming the select gates 118a˜118d and the conductive layer 118e, a spacer 120a is formed on one side of the memory cell column 119 and one side of the conductive layer 118e. The spacers 120a is formed, for example, by depositing insulating material over the substrate 100 to form an insulating layer (not shown) and performing an anisotropic etching operation. The insulating layer is fabricated using a material having an etching selectivity different from the cap layer 110a and the inter-gate dielectric layer 116 such as silicon nitride. Because the insulating layer has an etching selectivity different from the cap layer 110a and the inter-gate dielectric layer 116, the cap layer 110a and the inter-gate dielectric layer 116 will not be removed to expose the conductive layer 108a when the spacers 120a are formed. Thereafter, a drain region 126 is formed in the substrate 100 (the substrate 100 on one side of the select gate 118a) on one side of the memory cell column 119.

As shown in FIG. 2B, a cover layer 128 is formed over the substrate 100. The cover layer 128 having a thickness between 300 Å to 500 Å is formed, for example, by performing a chemical vapor deposition process. Thereafter, the cover layer 128 is patterned to expose the area for forming a silicide layer.

As shown in FIG. 2C, a silicidation process is carried out to convert the polysilicon material constituting the select gates 118a˜118d into silicide material. The silicidation process includes forming a metallic layer over the substrate 100, performing an annealing operation to transform the polysilicon constituting the select gates 118a˜118d and the conductive layer 118e into silicide and removing metallic layer not participating in the reaction with the silicon. After that, other processes are carried out to form a complete non-volatile memory. Since the remaining steps should be familiar to anyone skill in the art of semiconductor production, a detailed description of those steps is omitted. In addition, the select gates 118a˜118d and the conductive layer 118e can be fabricated using one of the following materials including, for example, titanium silicide, tantalum silicide, molybdenum silicide, cobalt silicide and nickel silicide.

In the aforementioned embodiment, the sheet resistance of the select gates 118a˜118d are lowered when the select gate 118a˜118d material change from polysilicon into silicide. Furthermore, before converting the select gate 118a˜118d polysilicon into silicide, the dopant concentration of the doped polysilicon can be adjusted to increase the threshold voltage of the select transistor. In addition, the aforementioned method of fabricating the non-volatile memory can integrate with complementary metal-oxide-semiconductor (CMOS) process without major alterations.

The present invention also provides a non-volatile memory structure. The non-volatile memory structure is shown in FIG. 11. As shown in FIG. 11, the non-volatile memory includes a substrate 100, a plurality of stacked gate structures 114a˜114d, a plurality of select gates 118a˜118d, an inter-gate dielectric layer 116, spacers 120a, a source region 115 and a drain region 126.

The stacked gate structures 114a 114d are disposed on the substrate 100. Each stacked gate structure includes a tunneling dielectric layer 102a, a floating gate (conductive layer 104a), an inter-gate dielectric layer 106a and a control gate (conductive layer 106a) formed on the substrate 100.

The tunneling dielectric layer 102a is a silicon oxide layer, the floating gate (the conductive layer 104a) is a doped polysilicon layer and the inter-gate dielectric layer is an oxide/nitride/oxide composite layer, for example. Obviously, the inter-gate dielectric layer 106a can also be an oxide/nitride composite layer. The control gate (the conductive layer 106a) is a silicide layer including, for example, a titanium silicide, tantalum silicide, molybdenum silicide, cobalt silicide or a nickel silicide layer. In another embodiment, the control gate (the conductive layer 106a) is a polycide layer, for example.

The select gates 118a˜118d are disposed on one side of the stacked gate structures 114a˜114d so that the stacked gate structures 114a˜114d are serially connected together to form a memory cell column 119. The select gates 118a˜118d are silicide layers including titanium silicide, tantalum silicide, molybdenum silicide, cobalt silicide or nickel silicide layers.

The inter-gate dielectric layer 116 is disposed between the stacked gate structures 114a˜114d and the select gates 118a˜118d. The inter-gate dielectric layer 116 between the stacked gate structures 114a˜114d and the select gates 118a˜118d serves as a select gate dielectric layer.

The spacers 120a are disposed on the sidewalls of the memory cell column 119. The source region 115 and the drain region 126 are disposed in the substrate on each side of the memory cell column 119.

In the aforementioned embodiment, the sheet resistance of the select gates 118a 118d and/or the control gate are lowered when the select gate 118a˜118d and/or the control gate material change from polysilicon into silicide. Furthermore, before converting doped polysilicon material constituting the conductive layer 108a (the control gate) and the select gate 118a˜118d into silicide, the dopant concentration of the doped polysilicon can be adjusted to increase the threshold voltage of the select transistor.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of manufacturing a non-volatile memory, comprising the steps of:
providing a substrate;
forming a plurality of stacked gate structures over the substrate, wherein each stacked gate structure comprises a tunneling dielectric layer, a floating gate, a first inter-gate dielectric layer and a control gate;
forming a source region in the substrate on an outer side of the stacked gate structures; forming a second inter-gate dielectric layer over the substrate;
forming a plurality of select gates on one side of the stacked gate structures, wherein the select gates connect the stacked gate structures together to form a memory cell column and the material constituting the select gates comprises doped polysilicon;
forming a drain region in the substrate on the other outer side of the stacked gate structures; and
performing a silicidation process to transform the material constituting the select gates from doped polysilicon into silicide.

2. The method of claim 1, wherein the silicidation process comprises:
forming a cover layer over the substrate;
patterning the cover layer to expose the select gates;
forming a metallic layer over the substrate;
performing an annealing treatment so that the metallic layer reacts with the material constituting the select gates to form a silicide layer; and
removing any metallic layer not participating in the reaction and the cover layer.

3. The method of claim 2, wherein the metallic layer comprises nickel and the silicide layer comprises a nickel silicide layer.

4. The method of claim 2, wherein the suicide layer is selected from a group consisting of titanium silicide, tantalum silicide, molybdenum silicide, cobalt silicide and nickel silicide.

5. The method of claim 1, wherein the material constituting the control gate comprises polycide.

6. The method of claim 1, wherein the material constituting the control gate comprises doped polysilicon.

7. The method of claim 1, wherein the stacked gate structures further comprises a cap layer over the control gates.

8. The method of claim 7, wherein the material constituting the cap layer and the cover layer comprises silicon nitride.

9. The method of claim 8, wherein the method further comprises a step of forming an insulating layer over the substrate and removing a portion of the insulating layer to form a pair of first spacers on the sidewall of the memory cell column.

10. The method of claim 1, wherein the second inter-gate dielectric layer comprises a high-temperature silicon oxide layer.

11. The method of claim 1, wherein the first inter-gate dielectric layer comprises an oxide/nitride/oxide composite layer.

12. A method of manufacturing a non-volatile memory, comprising the steps of:
providing a substrate;
forming a plurality of stacked gate structures over the substrate, wherein each stacked gate structure comprises a tunneling dielectric layer, a floating gate, a first inter-gate dielectric layer, a control gate, a cap layer and the material constituting the control gate comprises doped polysilicon;
forming a source region in the substrate on an outer side of the stacked gate structures;
forming a second inter-gate dielectric layer over the substrate;
forming a plurality of select gates on one side of the stacked gate structures, wherein the select gates serially connect the stacked gate structures together to form a memory cell column and the material constituting the select gates comprises doped polysilicon;
forming a drain region in the substrate on the other outer side of the stacked gate structures; and
performing a silicidation process to transform the polysilicon constituting the select gates and the control gates into silicide material.

13. The method of claim 12, wherein the silicidation process comprises:
forming a cover layer over the substrate, wherein the cover layer exposes the select gates and the control gate;
forming a metallic layer over the substrate;
performing an annealing treatment so that the metallic layer reacts with the control gates and the select gates to form a silicide layer; and
removing any metallic layer not participating in the reaction and the cover layer.

14. The method of claim 13, wherein the silicide layer is selected from a group consisting of titanium silicide, tantalum silicide, molybdenum silicide, cobalt silicide and nickel silicide.

15. The method of claim 13, wherein the metallic layer comprises nickel and the silicide layer comprises a nickel silicide layer.

16. A non-volatile memory, comprising:
a substrate;
a plurality of stacked gate structures disposed on the substrate, wherein each stacked gate structure comprises a tunneling dielectric layer, a floating gate, a first inter-gate dielectric layer and a control gate sequentially formed over the substrate;
a plurality of select gates disposed on one sidewall of the stacked gate structures, wherein the select gates serially connect the stacked gate structures together to form a memory cell column; and
a second inter-gate dielectric layer disposed between the stacked gate structures and the select gates;
characterized in that the select gates are formed by silicide material.

17. The non-volatile memory of claim 16, wherein the material constituting the select gates is selected from a group consisting of titanium silicide, tantalum silicide, molybdenum silicide, cobalt silicide and nickel silicide.

18. The non-volatile memory of claim 16, wherein the material constituting the control gate comprises metallic silicide.

19. The non-volatile memory of claim 16, wherein the material constituting the control gates is selected from a group consisting of titanium silicide, tantalum silicide, molybdenum silicide, cobalt silicide and nickel silicide.

20. The non-volatile memory of claim 16, wherein the first inter-gate dielectric layer comprises an oxide/nitride/nitride composite layer.

21. The non-volatile memory of claim 16, wherein the second inter-gate dielectric layer comprises a high-temperature silicon oxide layer.

22. The non-volatile memory of claim 16, wherein the material constituting the control gate comprises polycide.
